(19) United States
(12) Patent Application Publication
(10) Pub. No.: US 2026/0305402 A1
(43) Pub. Date: Oct. 1, 2026

(54) SEMICONDUCTOR PACKAGE

(71) Applicant: MEDIATEK INC., Hsinchu City (TW)

(72) Inventors: Sang-Mao CHIU, Hsinchu City (TW); Ching-Ku LIAO, Hsinchu City (TW); Yi-Ting KUO, Hsinchu City (TW); Wei-Chen CHANG, Hsinchu City (TW)

(21) Appl. No.: 19/571,658

(22) Filed: Mar. 19, 2026

Related U.S. Application Data
(60) Provisional application No. 63/777,043, filed on Mar. 25, 2025.

(51) Int. Cl. H10W 70/63; H10W 70/652; H10W 70/655; H10W 70/685; H10W 74/10; H10W 74/15; H10W 90/00

(52) U.S. Cl. CPC H10W 70/635; H10W 70/652; H10W 70/655; H10W 70/685; H10W 70/686; H10W 74/141; H10W 74/15; H10W 90/724

(57) ABSTRACT

A semiconductor package is provided. The semiconductor package includes a substrate and a die. The die is mounted on the substrate. The substrate includes a first core layer, a second core layer, and a first pair of Prepreg (PP) layers. The second core layer is stacked on the first core layer. The first pair of Prepreg (PP) layers is disposed between the first core layer and the second core layer.

### CROSS REFERENCE TO RELATED APPLICATIONS

This application claims the benefit of U.S. Provisional Application No. 63/777,043, filed on Mar. 25, 2025, the entirety of which is incorporated by reference herein.

### TECHNICAL FIELD

The present disclosure relates to a semiconductor package and, in particular, it relates to a multi-core package substrate having through hole conductive components of different lengths.

### BACKGROUND

In order to ensure miniaturization and multi-functionality of electronic products and communication devices, it is desired that semiconductor packages be small in size, support multi-pin connection, operate at high speeds, and have high functionality. In recent years, demand has increased for semiconductor package structures with a small size, a high I/O pad-density, high operation frequencies, better functionality, and better electrical performance and reliability, all at a low cost. However, in package substrates, there is a tradeoff between power integrity and signal integrity.

Thus, a novel package substrate is desirable.

### BRIEF SUMMARY

An embodiment of the present disclosure provides a semiconductor package. The semiconductor package includes a substrate and a die. The die is mounted on the substrate. The substrate includes a first core layer, a second core layer, and a first pair of Prepreg (PP) layers. The second core layer is stacked on the first core layer. The first pair of Prepreg (PP) layers is disposed between the first core layer and the second core layer.

An embodiment of the present disclosure provides a semiconductor package. The semiconductor package includes a substrate and a die. The substrate includes a core structure. The core structure includes at least two cores and at least three pairs of Prepreg (PP) layers stacked on each other. The at least two cores are arranged in such a way that they alternate with the at least three pairs of PP layers. The core structure has a first plating through hole (PTH) passing through the at least two cores and one of the three pairs of PP layers, and a second plating through hole (PTH) passing through the at least two cores and the three pairs of PP layers. The die is mounted on the substrate and coupled to the first PTH and the second PTH.

In addition, an embodiment of the present disclosure provides a semiconductor package. The semiconductor package includes a substrate and a die. The substrate includes N core layers, 2N+2 Prepreg (PP) layers, a first plating through hole (PTH), and a second plating through hole (PTH), wherein N is an integer greater than or equal to 2. The N core layers are stacked on each other. The 2N+2 Prepreg (PP) layers are disposed on the N core layers. A top surface and a bottom surface of each of the N core layers are directly covered by the 2 PP layers only. The first plating through hole (PTH) passes through the 2N−2 PP layers. The second plating through hole (PTH) passes through the 2N+2 PP layers. The die is mounted on the substrate and coupled to the first PTH and the second PTH

### BRIEF DESCRIPTION OF THE DRAWINGS

The present disclosure can be more fully understood by reading the subsequent detailed description and examples with references made to the accompanying drawings, wherein:

FIG. 1 is a schematic cross-sectional view of a semiconductor package in accordance with some embodiments of the disclosure;

FIG. 2 is a schematic cross-sectional view of a semiconductor package in accordance with some embodiments of the disclosure;

FIG. 3 is a schematic cross-sectional view of a semiconductor package in accordance with some embodiments of the disclosure;

FIG. 4 is a schematic cross-sectional view of a semiconductor package in accordance with some embodiments of the disclosure;

FIG. 5 is a schematic cross-sectional view of a semiconductor package in accordance with some embodiments of the disclosure; and

FIG. 6 is a schematic top view of the semiconductor package of FIG. 5 in accordance with some embodiments of the disclosure.

### DETAILED DESCRIPTION

The following description is made for the purpose of illustrating the general principles of the disclosure and should not be taken in a limiting sense. The scope of the disclosure is best determined by reference to the appended claims.

In the existing technology, the architecture of the package substrate consists of a single-layer core combined with a plating through hole (PTH) that goes through the single-layer core. With the advancement of technology and the increasing application demands, more and more scenarios require high-bandwidth signal transmission. However, package substrates are no longer suitable for these high-bandwidth, high-frequency signal transmission requirements. Therefore, there is a need for innovative package substrate designs.

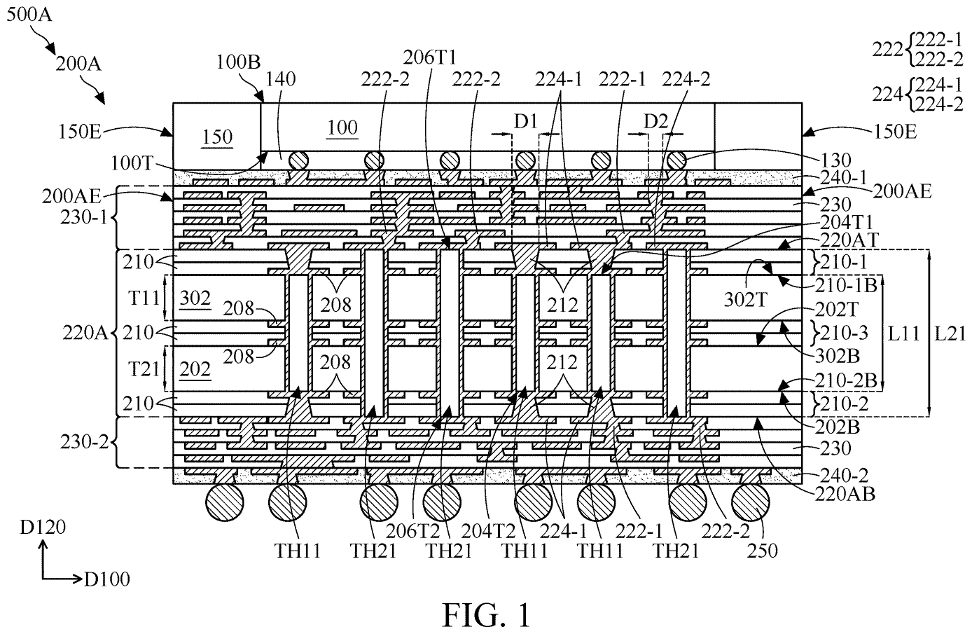

FIG. 1 is a schematic cross-sectional view of a semiconductor package 500A in accordance with some embodiments of the disclosure. In FIG. 1 and the following figures, a direction D100 is defined as horizontal directions (also regarded as the extending directions of conductive layers and/or conductive traces), and a direction D120 is defined as a vertical direction (also regarded as the extending direction of the through via and/or vias).

The semiconductor package 500A includes a substrate 200A and a die 100. For example, the substrate 200A may include a multi-layered package substrate (e.g., a flip-chip ball grid array (FCBGA) substrate). The substrate 200A may provide mechanical support and electrical connections between the die (e.g., the die 100) and conductive structures (e.g., conductive structures 250) attached to the top and bottom surfaces of the substrate 200A. The substrate 200A may have various types including, for example, cored substrates, including thin core, thick core (e.g., laminate BT (bismaleimide-triazine resin) or FR-4 type fibrous board material), and laminate core. Alternatively, the cored package substrates, for example, can be built up layer by layer around a central core, with layers of conductive material (usually copper) separated by layers of insulating dielectric, with interlayer connections being formed with through holes or vias (microvias).

In some embodiments, the substrate 200A includes that a core structure 220A and substrate redistribution layers (RDLs) 230-1 and 230-2. In addition, the core structure 220A includes two core layers 202, 302 and three core redistribution layers (RDLs) 210-1, 210-2 and 210-3. The substrate 200A may also be called a multi-layer duo core substrate.

As shown in FIG. 1, the core layer 202 has a top surface 202T and a bottom surface 202B. The core layer 302 is stacked on the core layer 202. The core layer 302 has a top surface 302T and a bottom surface 302B. The bottom surface 302B of the core layer 302 may face the top surface 202T of the core layer 202. In the core structure 220A, the thickness T11 of the core layer 202 may be the same as, larger than or smaller than the thickness T21 of the core layer 302.

In some embodiments, the core layers 202 and 302 may be formed of the same or similar materials. For example, the core layers 202 and 302 may be formed of an organic material including polypropylene, prepreg (PP), FR-4, T-glass, S-glass, polyimide, and/or other epoxy laminate material or an inorganic material including ceramic, glass, silicon or the like.

The core redistribution layers 210-3 and 210-2 are disposed on and in contact with the top surface 202T and the bottom surface 202B of the core layer 202, respectively. The core redistribution layers 210-1 and 210-3 are disposed on and in contact with the top surface 302T and the bottom surface 302B of the core layer 302, respectively. The core redistribution layers 210-3 is disposed between the core redistribution layers 210-1 and 210-2.

In some embodiments, each of the core redistribution layers 210-1 and 210-2 includes one pair of prepreg (PP) layers (two PP layers) 210, and one or more vias 212 and conductive layers 208 disposed in the pair of prepreg (PP) layers 210. In some embodiments, the core redistribution layer 210-3 includes one pair of prepreg (PP) layers 210 (i.e., two PP layers 210) and conductive layers 208. The pair of PP layers 210 of the core redistribution layers 210-1, 210-2 and 210-3 are directly stacked each other. Each pair of prepreg (PP) layers 210 (i.e., two PP layers) may be formed in the same process or in different processes. The two PP layers in each pair are in contact with each other and define an interface between them.

The pair of PP layers 210 of the core redistribution layer 210-3 is disposed directly between the top surface 202T of the core layer 202 and the bottom surface 302B of the core layer 302. In addition, the pair of PP layers 210 of the core redistribution layer 210-1 is disposed on the top surface 302T of the core layer 302 and opposite the pair of PP layers 210 of the core redistribution layer 210-3. The pair of PP layers 210 of the core redistribution layer 210-2 is disposed on the bottom surface 202B of the core layer 202 and opposite the pair of PP layers 210 of the core redistribution layer 210-3. It should be noted that there is no via positioned in the pair of PP layers 210 of the core redistribution layer 210-3.

In other words, each of the top surface 202T of the core layer 202, the bottom surface 202B of the core layer 202, the top surface 302T of the core layer 302, and the bottom surface 302B of the core layer 302 is directly covered by only one pair of prepreg (PP) layers 210.

In another aspect, the PP layers 210 of the core redistribution layers 210-3, and 210-2 are symmetrically disposed on the top surface 202T and the bottom surface 202B of the core layer 202. The PP layers 210 of the core redistribution layers 210-1 and 210-3 are symmetrically disposed on the top surface 302T and the bottom surface 302B of the core layer 302. For example, the number of PP layers 210 of the core redistribution layer 210-1 is the same as the number of PP layers 210 of the core redistribution layer 210-3. The number of PP layers 210 of the core redistribution layer 210-3 is the same as the number of PP layers 210 of the core redistribution layer 210-2. Each of the core redistribution layers 210-1, 210-2 and 210-3 include two PP layers 210. In some embodiments, the PP layers 210 may be formed using a lamination process.

As shown in FIG. 1, the core structure 220A of the substrate 200A has separated plating through holes (PTH) TH11 and TH21 embedded it. In some embodiments, the plating through hole (PTH) TH11 passes through the core layers 202 and 302 and the pair of PP layers 210 of the core redistribution layer 210-3 between the core layers 202 and 302. In addition, the plating through hole (PTH) TH21 passes through the core structure 220A including the core layers 202 and 302, the pair of PP layers 210 of the core redistribution layers 210-1, the pair of PP layers 210 of the core redistribution layer 210-2 and the pair of PP layers 210 of the core redistribution layer 210-3. In some embodiments, the plating through holes (PTHs) TH11 and TH21 may be formed in the same process.

In some embodiments, in the direction D120, the dimension L11 (or the length L11) of the plating through hole (PTH) TH11 is substantially equal to the total thickness of the core layers 202, 302 and the pair of PP layers 210 of the core redistribution layer 210-3 between the core layers 202 and 302. In addition, the dimension L21 (or the length L21) of the plating through hole (PTH) TH21 is substantially equal to the total thickness of the core layers 202 and 302, the pair of PP layers 210 of the core redistribution layers 210-3 between the core layers 202 and 302, the pair of PP layers 210 of the core redistribution layer 210-1 and the pair of PP layers 210 of the core redistribution layer 210-2. Therefore, the dimension L11 of the plating through hole (PTH) TH11 is smaller than the dimension L21 of the plating through hole (PTH) TH21.

In some embodiments, in the direction D100 (also serve as a radial direction of the plating through holes (PTHs) TH11 and TH21), the plating through holes (PTH) TH11 and TH21 may have the same or different dimensions (or diameters).

In another aspect, the core structure 220A of the substrate 200A includes at least two core layers 202, 302 and at least three pairs of PP layers 210 stacked on each other. In addition, the two core layers 202, 302 are arranged in such a way that they alternate with the three pairs of PP layers 210. In some embodiments, the core structure 220A has a plating through hole (PTH) TH11 passing through the two core layers 202, 302 and one of the three pairs of PP layers 210. In addition, the core structure 220A has a plating through hole (PTH) TH21 passing through the two core layers 202, 302 and the three pairs of PP layers 210.

In yet another aspect, the core structure 220A of the substrate 200A includes N core layers (e.g., the core layers 202 and 302) stacked on each other, wherein N is an integer greater than or equal to 2. The core structure 220A further includes 2N+2 Prepreg (PP) layers 210, a plating through hole (PTH) TH11 and a plating through hole (PTH) TH21. The 2N+2 Prepreg (PP) layers are disposed on the N core layers. In addition, the top surface and the bottom surface of each of the N core layers (e.g., the top surface 202T and the bottom surface 202B of the core layer 202 and the top surface 302T and the bottom surface 302B of the core layer 302) are directly covered by the 2 PP layers 210 only. The plating through hole (PTH) TH11 passes through the 2N−2 PP layers 210. The plating through hole (PTH) TH21 passes through the 2N+2 PP layers 210.

In some embodiments, two terminals 204T1, 204T2 of the plating through hole (PTH) TH11 are not aligned with two corresponding terminals 206T1, 206T2 of the plating through hole (PTH) TH21 in the direction D100. For example, the two terminals 204T1, 204T2 of the plating through hole (PTH) TH11 may be close to the top surface 302T of the core layer 302 and the bottom surface 202B of the core layer 202, respectively. In addition, the two terminals 204T1, 204T2 of the plating through hole (PTH) TH11 may be exposed from the top surface 302T of the core layer 302 and the bottom surface 202B of the core layer 202, respectively. In some embodiments, the terminal 204T1 of the plating through hole (PTH) TH11 may be flush with the top surface 302T of the core layer 302, the terminal 204T2 of the plating through hole (PTH) TH11 may be flush with the bottom surface 202B of the core layer 202. In some embodiments, the two terminals 206T1, 206T2 of the plating through hole (PTH) TH21 may be close to the top surface 220AT and the bottom surface 220AB of the core structure 220A, respectively. In addition, the two terminals 206T1, 206T2 of the plating through hole (PTH) TH21 may be exposed from the top surface 220AT and the bottom surface 220AB of the core structure 220A, respectively. In some embodiments, the terminal 206T1 of the plating through hole (PTH) TH21 may be flush with the top surface 220AT of the core redistribution layer 210-1, the terminal 206T2 of the plating through hole (PTH) TH21 may be flush with the bottom surface 220AB of the core redistribution layer 210-2.

In some embodiments, the terminal 204T1 of the plating through hole (PTH) TH11 and the terminal 206T1 of the plating through hole (PTH) TH21 are close to opposite surfaces of the pairs of PP layers 210 of the core redistribution layer 210-1. For example, the terminal 204T1 of the plating through hole (PTH) TH11 is close to a surface (also an inner surface 210-1B of the core redistribution layer 210-1) of the pair of PP layers 210 of the core redistribution layer 210-1 that is close to the top surface 302T of the core layer 302. The terminal 206T1 of the plating through hole (PTH) TH21 is close to a surface (also the top surface 220AT) of the pair of PP layers 210 of the core redistribution layer 210-1 that is close to the top surface 220AT of the core structure 220A.

In other words, the terminal 204T1 of the plating through hole (PTH) TH11 is close to an inner surface (also the inner surface 210-1B of the core redistribution layer 210-1) of the pairs of PP layers 210 of the core redistribution layer 210-1 that is close to the core layer 302. The terminal 206T1 of the plating through hole (PTH) TH21 is close to an outer surface (also the top surface 220AT) of the pair of PP layers 210 of the core redistribution layer 210-1 that is away from the core layer 302.

Similarly, the terminal 204T2 of the plating through hole (PTH) TH11 and the terminal 206T2 of the plating through hole (PTH) TH21 are close to opposite surfaces of the pair of PP layers 210 of the core redistribution layer 210-2. For example, the terminal 204T2 of the plating through hole (PTH) TH11 is close to a surface (also an inner surface 210-2B of the core redistribution layer 210-2) of the pair of PP layers 210 of the core redistribution layer 210-2 that is close to the bottom surface 202B of the core layer 202. The terminal 206T2 of the plating through hole (PTH) TH21 is close to a surface (also the bottom surface 220AB) of the pair of PP layers 210 of the core redistribution layer 210-2 that is close to the bottom surface 220AB of the core structure 220A.

In other words, the terminal 204T2 of the conductive material 204 in the plating through hole (PTH) TH11 is close to an inner surface (also the inner surface 210-2B of the core redistribution layer 210-2) of the pair of PP layers 210 of the core redistribution layer 210-2 that is close to the core layer 202. The terminal 206T1 of the conductive material 206 in the plating through hole (PTH) TH21 is close to an outer surface (also the bottom surface 220AB) of the pair of PP layers 210 of the core redistribution layer 210-1 that is away from the core layer 202.

In some embodiments, each of the plating through hole (PTH) TH11 and the plating through hole (PTH) TH21 includes a thin conductive layer (not shown) lining an inner wall of a hole passing through the core layers 202 and 302 to accommodate the corresponding plating through hole (PTH). In some embodiments, as shown in FIG. 1, the conductive layer in each of the plating through hole (PTH) TH11 and the plating through hole (PTH) TH21 may have a hollow pillar shape. In some embodiments, the thin conductive layer includes copper or nickel-copper.

In some embodiments, each of the plating through hole (PTH) TH11 and the plating through hole (PTH) TH21 may optionally include a non-conductive material (not shown) filling the remaining spaces of the hole and surrounded by the thin conductive layer. In some embodiments, the non-conductive material includes epoxy resin, such as an ink.

As shown in FIG. 1, the conductive layers 208 of the core redistribution layers 210-1, 210-2 and 210-3 may partially cover and be in contact with the top surface 202T and the bottom surface 202B of the core layer 202, and the top surface 302T and the bottom surface 302B of the core layer 302. In addition, the pair of PP layers 210 of the core redistribution layers 210-1, 210-2 and 210-3 may be disposed on the corresponding conductive layers 208, respectively. In addition, the pair of PP layers 210 of the core redistribution layers 210-1 and 210-2 may cover the conductive layers 208 and the plating through hole (PTH) TH11.

As shown in FIG. 1, the conductive layers 208 of the core redistribution layers 210-1 and 210-2 in contact with the plating through hole (PTH) TH11 are formed directly on the top surface 302T of the core layer 302 and the bottom surface 202B of the core layer 202, respectively. In some embodiments, the conductive layers 208 of the core redistribution layers 210-1 and 210-2 may cover the plating through hole (PTH) TH11, and the conductive layers 208 of the core redistribution layer 210-3 may surround the corresponding plating through holes (PTHs) TH11 and TH21. For example, the conductive layers 208 of the core redistribution layers 210-1 and 210-2 and the conductive layers 208 of the core redistribution layer 210-3 may fully cover and/or surround the plating through hole (PTH) TH11. For example, some of the conductive layers 208 of the core redistribution layers 210-1 to 210-3 may surround the plating through hole (PTH) TH21. In addition, the conductive layers 208 may be connected (coupled) to the plating through holes (PTHs) TH11 and TH21. If the plating through hole (PTH) TH11 or TH21 is used for grounding, the conductive layers 208 surrounding the grounding plating through hole (PTH) TH11 or TH21 may serve as ground planes).

In some embodiments, the conductive layer 208 at each of levels of the core redistribution layers 210-1, 210-2 and 210-3 may include a set of conductive traces (not shown) or conductive planes (also called ground planes) (not shown). In some embodiments, the conductive layers 208 include a conductive material, such as metals including copper, gold, silver, or other applicable metals. For example, the conductive layers 208 may be copper traces 208.

As shown in FIG. 1, the vias 212 are disposed in the pair of PP layers 210 of the core redistribution layers 210-1 and 210-2. The vias 212 are disposed directly on the terminals 204T1, 204T2 of the corresponding plating through hole (PTH) TH11. Each of the vias 212 may be formed passing through the pair of PP layers 210 of the core redistribution layers 210-1 and 210-2 to be coupled to the corresponding conductive layers 208 in contact with the plating through hole (PTH) TH11 and covered by the pair of PP layers 210. It should be noted that the vias 212 are not in contact with (separated form) the plating through hole (PTH) TH21. In some embodiments, the number of vias 212 is twice the number of plating through holes (PTHs) TH11. In some embodiments, the vias 212 may be formed by laser-drilling.

As shown in FIG. 1, the semiconductor structure 500A further includes substrate redistribution layers (RDLs) 230-1 and 230-2. The substrate redistribution layers 230-1 and 230-2 are disposed on the core redistribution layers 210-1 and 210-2, respectively. In some embodiments, each of the substrate redistribution layers 230-1 and 230-2 includes one or more conductive layers 224 (including conductive layers 224-1 and 224-2), one or more vias 222 (including vias 222-1 and 222-2) disposed in one or more dielectric layers 230. It should be noted that the number of vias 222, the number of conductive layers 224 and the number of dielectric layers 230 shown in FIG. 1 are only an example and is not a limitation to the present disclosure.

In some embodiments, the substrate redistribution layers 230-1 and 230-2 are connected to (or coupled to) the plating through hole (PTH) TH11 and the plating through hole (PTH) TH21. More specifically, the plating through hole (PTH) TH11 may be coupled to the conductive layers 208 of the core redistribution layers 210-1 and 210-2. The conductive layers 208 may be connected to (or coupled to) the corresponding vias 212 in the pair of PP layers 210 of the core redistribution layers 210-1 and 210-2. The vias 212 located in the pair of PP layers 210 may be connected to (or coupled to) the vias 222 and the conductive layers 224 in the substrate redistribution layers 230-1 and 230-2. In other words, the plating through hole (PTH) TH11 may be coupled to the substrate redistribution layers 230-1 and 230-2 through the conductive layers 208 and the vias 212 of the core redistribution layers 210-1 and 210-2. In addition, the plating through hole (PTH) TH21 may be directly connected to (or coupled to) the substrate redistribution layers 230-1 and 230-2 without using the conductive layers 208 and the vias 212 of the core redistribution layers 210-1 and 210-2.

As shown in FIG. 1, the conductive layers 224-1 and 224-2 may partially cover the top surface 220AT and the bottom surface 220AB of the core structure 220A. In addition, the dielectric layers 230 of the substrate redistribution layers 230-1 and 230-2 may be disposed on the conductive layers 224-1 and 224-2, respectively. In addition, the dielectric layers 230 of the substrate redistribution layers 230-1 and 230-2 may cover the conductive layers 224-1 and 224-2.

In some embodiments, the conductive layers 224-1 and 224-2 at each of levels of the substrate redistribution layers 230-1 and 230-2 may include a set of conductive traces (not shown) or conductive planes (also called ground planes) (not shown). In some embodiments, the conductive layer 224-1 is directly coupled to the vias 212 of the core redistribution layers 210-1 and 210-2 at the interface (also positioned at the top surface 220AT of the core structure 220A) between the core redistribution layer 210-1 and the corresponding substrate redistribution layers 230-1 and the interface (also positioned at the bottom surface 220AB of the core structure 220A) between the core redistribution layer 210-2 and the corresponding substrate redistribution layers 230-2. In some embodiments, the conductive layer 224-2 covers and is directly coupled to the plating through hole (PTH) TH21. In some embodiments, the conductive layers 208 and the conductive layers 224 may have the same or similar materials and processes.

As shown in FIG. 1, the vias 222-1 and 222-2 are disposed in the dielectric layers 230 of the substrate redistribution layers 230-1 and 230-2. The vias 222-1 may be formed passing through the dielectric layers 230 of the substrate redistribution layers 230-1 and 230-2 to be coupled to the plating through hole (PTH) TH11 by the conductive layers 208 covered by the pair of PP layers 210 and the conductive layers 224-1 covered by the dielectric layers 230. The vias 222-2 may be formed passing through the dielectric layers 230 of the substrate redistribution layers 230-1 and 230-2 to be coupled to the plating through hole (PTH) TH21 only by the conductive layers 224-2 covered by the dielectric layers 230. In some embodiments, the vias 212 and the vias 222 may have the same or similar materials and processes.

In some embodiments, the dielectric layers 230 of the substrate redistribution layers 230-1 and 230-2 are symmetrically (or asymmetrically) disposed the top surface 220AT and the bottom surface 220AB of the core structure 220A. In some embodiments, at least two dielectric layers 230 are disposed on the top surface 220AT and the bottom surface 220AB of the core structure 220A and connected to the pair of PP layers 210 of the core redistribution layers 210-1 and 210-2. In other words, there are M dielectric layers 230 disposed on each of the top surface 220AT and the bottom surface 220AB of the core structure 220A, wherein M is an integer greater or equal to 1. The M dielectric layers 230 are connected to the pair of PP layers 210 of each of the core redistribution layers 210-1 and 210-2. For example, the number of dielectric layers 230 of the substrate redistribution layers 230-1 is the same as (or different from) the number of dielectric layers 230 of the substrate redistribution layers 230-2.

In some embodiments, the pair of PP layers 210 of the core redistribution layers 210-1 to 210-3 and the dielectric layer 230 of the substrate redistribution layers 230-1 and 230-2 are made of different materials and formed by different processes. In this embodiment, the dielectric layer 230 includes Ajinomoto Build-Up Film (ABF). In this embodiment, the dielectric layer 230 may be formed by coating or lamination.

In some embodiments, the dielectric constant of the dielectric layer 230 may be different from the dielectric constant of the PP layer 210. For example, the dielectric constant of the dielectric layer 230 may be lower than the dielectric constant of the PP layer 210.

Due to the characteristics of materials and fabrication processes of the PP layer 210 and the dielectric layer 230, the core redistribution layers 210-1 and 210-2 and the substrate redistribution layers 230-1 and 230-2 may have different routing densities. For example, when the PP layer 210 and the dielectric layer 230 is formed of ABF, the routing density of the substrate redistribution layers 230-1 and 230-2 may be larger than the routing density of the core redistribution layers 210-1 and 210-2.

The conductive traces of the conductive layers 208 of the core redistribution layers 210-1 and 210-2 may have first minimum line width and spacing, and the conductive traces of the conductive layers 224 of the substrate redistribution layers 230-1 and 230-2 may have second minimum line width and spacing smaller than the first minimum line width and spacing. In addition, the vias 212 of the core redistribution layers 210-1 and 210-2 may have a first diameter D1, and the vias 222 of the substrate redistribution layers 230-1 and 230-2 may have a second diameter D2 smaller than the first diameter D1. In some embodiments, the thickness of each PP layer 210 is greater than the thickness of each dielectric layer 230; therefore, the first diameter D1 may be greater than the second diameter D2.

As shown in FIG. 1, the semiconductor structure 500A further includes solder mask layers 240-1 and 240-2 disposed over the corresponding substrate redistribution layers 230-1 and 230-2. In some embodiments, the solder mask layers 240-1 and 240-2 may cover the conductive layers 224 on the outermost dielectric layers 230 of the substrate redistribution layers 230-1 and 230-2. In addition, the solder mask layers 240-1 and 240-2 may have openings (not shown) to expose corresponding conductive pads (not shown). In some embodiments, the solder mask layers 240-1 and 240-2 may include an epoxy resin.

In some embodiments, the core structure 220A of the semiconductor structure 500A including multiple pairs of PP layers 210 may improve the mechanical strength of the core structure 220A to withstand various external forces without breaking or yielding.

As shown in FIG. 1, the die 100 is flipped to be mounted on the substrate 200A opposite the conductive structures 250 by a bonding process. The die 100 is mounted on the substrate 200A using conductive bumps 130. In addition, the die 100 is electrically connected to the conductive structures 250 by the substrate redistribution layers 230-1 and 230-2 and the plating through holes (PTH) TH11 and TH21 of the substrate 200A. The die 100 may cover a portion of the plating through holes (PTH) TH11 and TH21.

The die 100 has a front surface 100T and a back surface 100B. Conductive pads (not shown) of the die 100 are disposed close to the front surface 100T to be electrically connected to the circuitry (not shown) of the die 100. Therefore, the front surface 100T of the die 100 also serves as an active surface of the die 100. In some embodiments, the die 100 is fabricated by a flip-chip technology. In addition, the die 100 is flipped to be disposed on the substrate 200A opposite the conductive structures 250. The front surface 100T (i.e., the active surface) of the die 100 may face the substrate 200A.

In some embodiments, the die 100 includes a system-on-chip (SoC) die, a logic device, a memory device, a radio frequency (RF) device, the like, or any combination thereof. For example, the die 100 may include a micro control unit (MCU) die, a microprocessor unit (MPU) die, a power management integrated circuit (PMIC) die, a radio frequency front end (RFFE) die, an accelerated processing unit (APU) die, a central processing unit (CPU) die, a graphics processing unit (GPU) die, an input-output (IO) die, a dynamic random access memory (DRAM) controller, a static random-access memory (SRAM), a high bandwidth memory (HBM), an application processor (AP) die, an application specific integrated circuit (ASIC) die, the like, or any combination thereof.

In some embodiments, the conductive bumps 130 are electrically connected between the conductive layers 224-1 of the substrate redistribution layers 230-1 of the substrate 200A and the die 100. In some embodiments, the conductive bumps 130 include a copper bump or a solder bump structure. For example, the conductive bumps 130 may be controlled collapse chip connection (C4) structures. In some embodiments, each of the conductive bumps 130 may include an under bump metallurgy (UBM) layer and a conductive ball structure on the under bump metallurgy (UBM) layer.

In some embodiments, the semiconductor package 500A may further include an underfill 140 filling the gaps between the die 100 and the substrate 200A, and the gaps between conductive bumps 130. The underfill 140 may laterally surround the chiplet conductive bumps 130. The underfill 140 may provide structural support for the die 100. The underfill 140 may further reduce thermal resistance from the die 100 to the substrate 200A. In addition, the underfill 140 may be disposed to compensate for differing coefficients of thermal expansion (CTEs) between the die 100 and the substrate 200A. In some embodiments, the underfill 140 may be formed of polymer, such as epoxy or another suitable material. In some embodiments, the underfill 140 may be dispensed with capillary force, and then may be cured through any suitable curing process.

As shown in FIG. 1, the semiconductor package 500A further includes a molding compound 150 disposed on and in contact with the solder mask layer 240-1. In some embodiments, the molding compound 150 may surround the die 100. The molding compound 150 may laterally surround the conductive bumps 130. In some embodiments, the back surface 100B of the die 100 may be exposed from the molding compound 150. In addition, edges 150E of the molding compound 150 are leveled with corresponding edges 200AE of the substrate 200A. In some embodiments, the direction D120 is substantially vertical to the top surface 302T of the core layer 302. The direction D100 is substantially parallel to the top surface 302T of the core layer 302 and substantially vertical to the edge 200AE (or edges 150E) shown in the FIG. 1.

In some embodiments, the molding compound 150 may be formed of a nonconductive material, such as an epoxy, a resin, a moldable polymer, or the like. In some embodiments, the molding compound 150 may be formed by a molding process including compression or injection process. For example, the molding compound 150 may be applied while substantially liquid, and then may be cured through a chemical reaction, such as in an epoxy or resin. In some other embodiments, the molding compound 150 may be an ultraviolet (UV) or thermally cured polymer applied as a gel or malleable solid capable of being disposed around the die, and then may be cured using a UV or thermally curing process. The molding compound 150 may be cured with a mold (not shown).

The semiconductor package 500A further includes conductive structures 250 disposed on the bottom surface 200AB of substrate 200A away from the die 100 and in contact with the corresponding the conductive pads (not shown) on the bottom surface 200B of the substrate 200. In some embodiments, the conductive structures 250 include a conductive ball structure such as a solder ball or a copper-core solder ball.

Additionally, the resonance of the grounding structure may adversely affect signal transmission such that the energy transmission is degraded around the resonance frequency and cannot be efficiently transmitted. By dividing the resonance cavity into two or three smaller and vertical stacked resonance cavities (or more resonance cavities) through the multi-layer core structure (e.g., the multi-layer core structure 220A), the resonance frequency of the grounding structure is pushed to a higher frequency, so that the resonance-affected frequency region is shifted away from an operating frequency band and the effective transmission bandwidth is increased. In general, the multi-layer core structure may include N core layers stacked in a vertical direction, such that the resonance cavity caused by the conventional single grounding structure is divided into N smaller and vertical stacked resonance cavities passing through different core layers (e.g., the core layers 202, 302). In some embodiments, adjacent core layers of the multi-layer core structure are separated by two prepreg (PP) layers, such that the multi-layer core structure includes at least two core layers and the two prepreg (PP) layers disposed between the at least two core layers to achieve the above-described effects, thereby making the semiconductor package suitable for high-frequency application environments and improving the applicable scenarios and scope of the product (semiconductor package).

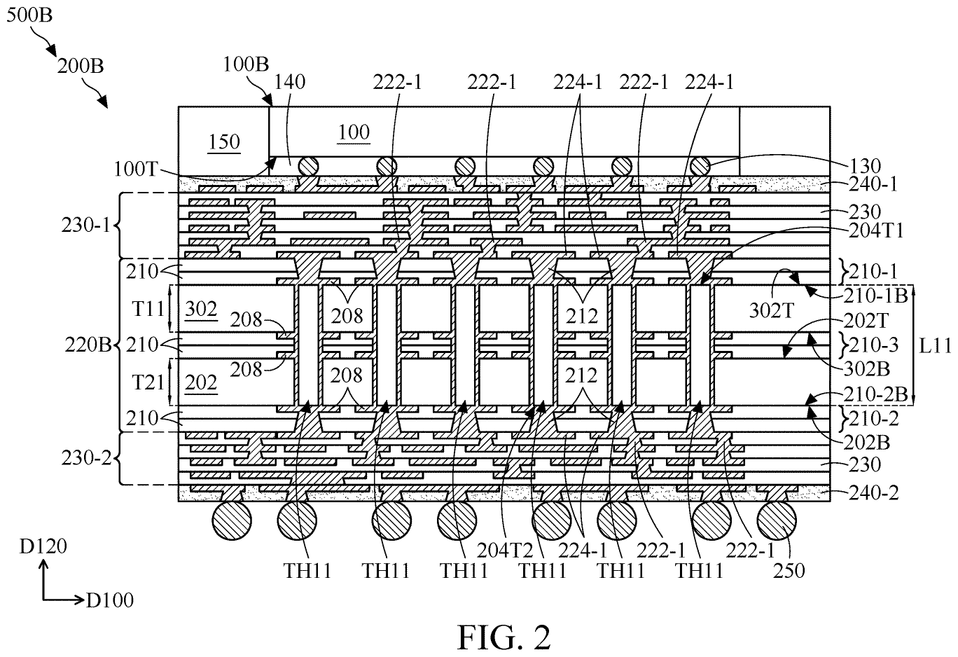

FIG. 2 is a schematic cross-sectional view of a semiconductor package 500B in accordance with some embodiments of the disclosure. Elements of the embodiments that are the same or similar to those previously described with reference to FIG. 1 are not repeated herein, in the interests of brevity. As shown in FIGS. 1 and 2, the difference between the semiconductor package 500A and the semiconductor package 500B at least includes that all plating through holes (PTHs) of a core structure 220B of the semiconductor package assembly 500B are plating through holes (PTHs) PH11.

In this embodiment, all the plating through holes (PTHs) (e.g., the plating through holes (PTHs) TH11) of the semiconductor package assembly 500B are covered by the pair of PP layers 210 of the core redistribution layer 210-1 and the pair of PP layers 210 of the core redistribution layer 210-2.

In this embodiment, all the plating through holes (PTHs) (e.g., the plating through holes (PTHs) TH11) of the semiconductor package assembly 500B pass through the core layers 202 and 302 and the pair of PP layers 210 of the core redistribution layer 210-3 between the core layers 202 and 302. The conductive layers 208 of the core redistribution layers 210-1 and 210-2 may cover the terminals 204T1 and 204T2 of every plating through hole (PTH) (e.g., the plating through holes (PTH) TH11). The vias 212 are disposed directly above the terminals 204T1 and 204T2 of every plating through holes (PTHs) (e.g., the plating through holes (PTHs) TH11) and coupled to the corresponding conductive layers 208 on the plating through hole (PTH) TH11. In this embodiment, the number of vias 212 is twice the total number of plating through holes (PTHs) (e.g., the plating through holes (PTHs) TH11) of the semiconductor package assembly 500B.

In another aspect, the core structure 220B of the substrate 200B includes at least two core layers 202, 302 and at least three pairs of PP layers 210 stacked on each other. In addition, the two core layers 202, 302 are arranged in such a way that they alternate with the three pairs of PP layers 210. In some embodiments, the core structure 220A has only one type of plating through holes (PTHs) (e.g., the plating through holes (PTHs) TH11) passing through the two core layers 202, 302 and one of the three pairs of PP layers 210.

In yet another aspect, the core structure 220B of the substrate 200B includes N core layers (e.g., the core layers 202 and 302) stacked on each other, wherein N is an integer greater than or equal to 2. The core structure 220B further includes 2N+2 Prepreg (PP) layers 210. The 2N+2 Prepreg (PP) layers are disposed on the N core layers. In addition, the top surface and the bottom surface of each of the N core layers (e.g., the top surface 202T and the bottom surface 202B of the core layer 202 and the top surface 302T and the bottom surface 302B of the core layer 302) are directly covered by the 2 PP layers 210 only. The core structure 220B further includes only one type of plating through holes (PTHs) (e.g., the plating through holes (PTHs) TH11) passing through the 2N−2 PP layers 210.

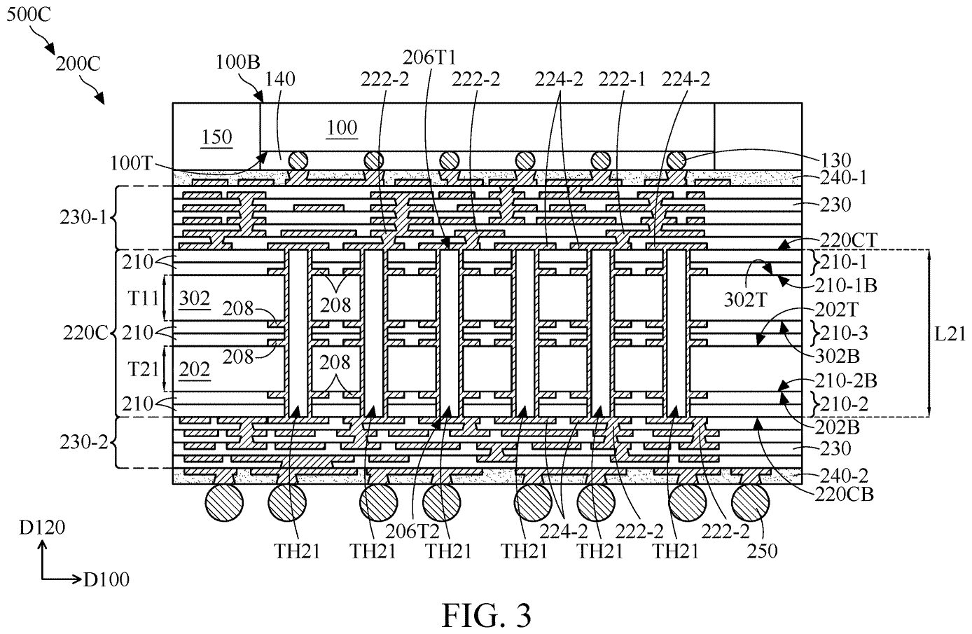

FIG. 3 is a schematic cross-sectional view of a semiconductor package 500C in accordance with some embodiments of the disclosure. Elements of the embodiments that are the same or similar to those previously described with reference to FIG. 1 are not repeated herein, in the interests of brevity. As shown in FIGS. 1 and 3, the difference between the semiconductor package 500A and the semiconductor package 500C at least includes that all plating through holes (PTHs) of a core structure 220C of the semiconductor package assembly 500C are plating through holes (PTHs) TH21.

In this embodiment, all the plating through holes (PTHs) (e.g., the plating through holes (PTHs) TH21) of the semiconductor package assembly 500C pass through the core structure 220C including the core layers 202 and 302, the pair of PP layers 210 of the core redistribution layer 210-1, the pair of PP layers 210 of the core redistribution layer 210-2 and the pair of PP layers 210 of the core redistribution layer 210-3. All the plating through holes (PTHs) (e.g., the plating through holes (PTHs) TH21) of the semiconductor package assembly 500C are exposed from the top surface 220CT and the bottom surface 220CB of the core structure 220C.

In this embodiment, there is no via 212 disposed in core structure 220C. In addition, all the conductive layers 208 of the core redistribution layers 210-1 to 210-3 may surround the corresponding plating through holes (PTHs) (e.g., the plating through holes (PTHs) TH21). The conductive layer 224-2 of the substrate redistribution layers 230-1 and 230-2 may cover the terminals 206T1 and 206T2 of every plating through hole (PTH) (e.g., the plating through hole (PTHs) TH21). In this embodiment, the number of conductive layers 224-2 in contact with the plating through holes (PTHs) TH21 is twice the total number of plating through holes (PTHs) (e.g., the plating through holes (PTHs) TH21) of the semiconductor package assembly 500C. In some embodiments, the terminal 206T1 of the plating through hole (PTH) TH21 may be flush with the top surface 220CT of the core redistribution layer 210-1, the terminal 206T2 of the plating through hole (PTH) TH21 may be flush with the bottom surface 220CB of the core redistribution layer 210-2.

In another aspect, the core structure 220C of the substrate 200C includes at least two core layers 202, 302 and at least three pairs of PP layers 210 stacked on each other. In addition, the two core layers 202, 302 are arranged in such a way that they alternate with the three pairs of PP layers 210. In some embodiments, the core structure 220C has only one type of plating through holes (PTHs) (e.g., the plating through holes (PTHs) TH21) passing through the two core layers 202, 302 and the three pairs of PP layers 210.

In yet another aspect, the core structure 220C of the substrate 200C includes N core layers (e.g., the core layers 202 and 302) stacked on each other, wherein N is an integer greater than or equal to 2. The core structure 220C further includes 2N+2 Prepreg (PP) layers 210. The 2N+2 Prepreg (PP) layers are disposed on the N core layers. In addition, the top surface and the bottom surface of each of the N core layers (e.g., the top surface 202T and the bottom surface 202B of the core layer 202 and the top surface 302T and the bottom surface 302B of the core layer 302) are directly covered by the 2 PP layers 210 only. The core structure 220B further includes only one type of plating through holes (PTHs) (e.g., the plating through holes (PTHs) TH21) passing through the 2N+2 PP layers 210.

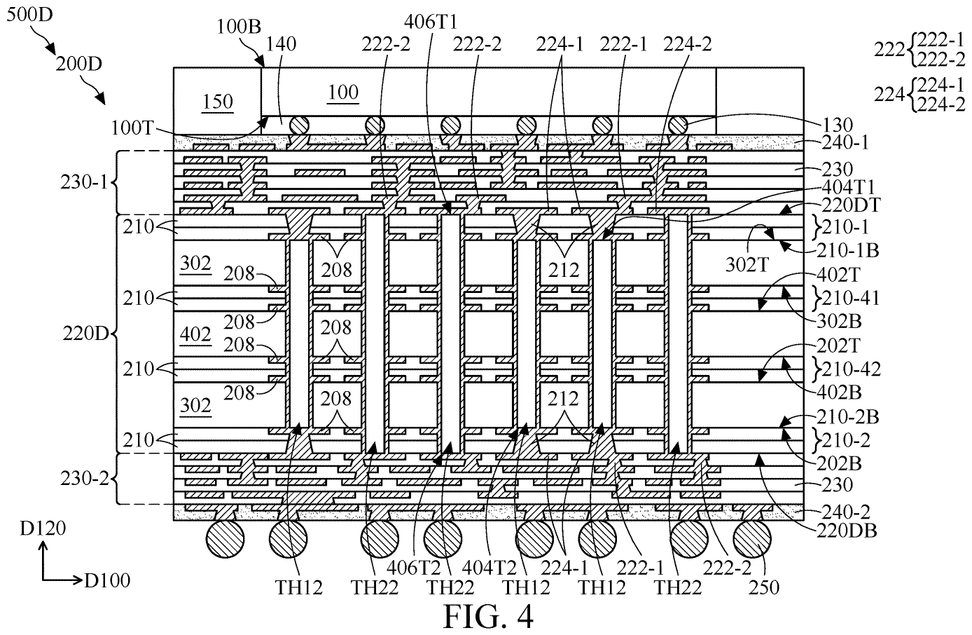

FIG. 4 is a schematic cross-sectional view of a semiconductor package 500D in accordance with some embodiments of the disclosure. Elements of the embodiments that are the same or similar to those previously described with reference to FIG. 1 are not repeated herein, in the interests of brevity. As shown in FIGS. 1 and 4, the difference between the semiconductor package 500A and the semiconductor package 500D at least includes that the semiconductor package 500D at least includes that a core structure 220D of a substrate 200D of the semiconductor package 500D includes three cores 202, 302 and 402, core redistribution layers 210-1, 210-2, 210-41, and 210-42 between the core redistribution layers 210-1 and 210-2. The substrate 200D may also be called a multi-layer triple core (or multi-core) substrate.

As shown in FIG. 4, the core layer 402 is disposed between the core layers 202 and 302 in the direction D120. The core redistribution layers 210-42 and 210-2 are disposed on and in contact with the top surface 202T and the bottom surface 202B of the core layer 202, respectively. The core redistribution layers 210-41, and 210-42 are disposed on and in contact with the top surface 402T and the bottom surface 402B of the core layer 402, respectively. The core redistribution layers 210-1 and 210-41 are disposed on and in contact with the top surface 302T and the bottom surface 302B of the core layer 302, respectively.

In some embodiments, each of the core redistribution layers 210-1 and 210-2 includes one pair of prepreg (PP) layers (two PP layers) 210, one or more vias 212 disposed in the pair of prepreg (PP) layers 210 and conductive layers 208. In some embodiments, each of the core redistribution layers 210-41, and 210-42 includes one pair of prepreg (PP) layers (two PP layers) 210 and conductive layers 208. The pair of PP layers 210 of the core redistribution layers 210-1, 210-2, 210-41, and 210-42 are directly stacked each other.

The pair of PP layers 210 of the core redistribution layer 210-42 is disposed directly between the top surface 202T of the core layer 202 and the bottom surface 402B of the core layer 402. The pair of PP layers 210 of the core redistribution layer 210-41 is disposed directly between the top surface 402T of the core layer 402 and the bottom surface 302B of the core layer 302. In addition, the pair of PP layers 210 of the core redistribution layer 210-1 is disposed on the top surface 302T of the core layer 302 and opposite the pair of PP layers 210 of the core redistribution layer 210-41. The PP pair of layers 210 of the core redistribution layer 210-2 is disposed on the bottom surface 202B of the core layer 202 and opposite the pair of PP layers 210 of the core redistribution layer 210-42. It should be noted that there is no via positioned in each of the PP layers 210 of the core redistribution layer 210-41 and 210-42.

In other words, each of the top surface 202T of the core layer 202, the bottom surface 202B of the core layer 202, the top surface 302T of the core layer 302, the bottom surface 302B of the core layer 302, the top surface 402T of the core layer 402, and the bottom surface 402B of the core layer 402 is directly covered by the one pair of prepreg (PP) layers 210 (i.e., two PP layers 210) only.

In another aspect, the PP layers 210 of the core redistribution layers 210-42, and 210-2 are symmetrically disposed on the top surface 202T and the bottom surface 202B of the core layer 202. The PP layers 210 of the core redistribution layers 210-41 and 210-42 are symmetrically disposed on the top surface 402T and the bottom surface 402B of the core layer 402. The PP layers 210 of the core redistribution layers 210-1 and 210-41 are symmetrically disposed on the top surface 302T and the bottom surface 302B of the core layer 302. In some embodiments, the number of PP layers 210 of the core redistribution layer 210-1 is the same as the number of PP layers 210 of the core redistribution layer 210-41. The number of PP layers 210 of the core redistribution layer 210-41 is the same as the number of PP layers 210 of the core redistribution layer 210-42. The number of PP layers 210 of the core redistribution layer 210-42 is the same as the number of PP layers 210 of the core redistribution layer 210-2. Each of the core redistribution layers 210-1, 210-2, 210-41, and 210-42 include two dielectric layers 210.

In addition, the pair of PP layers 210 of the core layer redistribution layer 210-1 disposed on the top surface 302T the core layer 302 and opposite the pair of PP layers 210 of each of the core layer redistribution layers 210-41 and 210-42. The pair of PP layers 210 of the core layer redistribution layer 210-2 is disposed on the bottom surface 202B of the core layer 202 and opposite the pair of PP layers 210 of each of the core layer redistribution layers 210-41 and 210-42. It should be noted that there is no via positioned in the pair of PP layers 210 of each of the core layer redistribution layers 210-41 and 210-42.

In the core layer structure 220D, the thickness T12 of the core layer 202, the thickness T22 of the core layer 302 and the thickness T32 of the core layer 402 may have the same or different values. In this embodiment, the total thickness (i.e., T12+T22+T32) of the core layers 202, 302 and 402 of the core layer structure 220D may be the same as, larger than or smaller than the total thickness (i.e., T11+T21) of the core layers 202 and 302 of the core layer structure 220A (FIG. 1), according to the design. In some embodiments, the core layers 202, 302 and 402 may be formed of the same or similar materials.

As shown in FIG. 4, the core layer structure 220D of the substrate 200D has separated plating through holes (PTHs) TH12 and TH22 embedded it. In this embodiment, the plating through hole (PTH) TH12 passes through the core layers 202, 302 and 402, and the pair of PP layers 210 of each of the core layer redistribution layers 210-41 and 210-42 between the core layers 202, 302 and 402. In addition, the plating through hole (PTH) TH22 passes through the core layer structure 220D including the core layers 202, 302 and 402 and the pair of PP layers 210 of each of the core layer redistribution layers 210-1, 210-2, 210-41 and 210-42.

In some embodiments, in the direction D120, a dimension L12 (the length L12) of the plating through hole (PTH) TH12 is substantially equal to the total thickness of the core layers 202, 302, 402 and the PP layers 210 of the core layer redistribution layers 210-41 and 210-42 between the core layers 202, 302 and 402. In addition, a dimension L22 (the length L22) of the plating through hole (PTH) TH22 is substantially equal to the total thickness of the core layers 202, 302, 402, the additional dielectric layers 210 between the core layers 202, 302 and 402, and the PP layers 210 of the core layer redistribution layers 210-1 and 210-2, 210-41 and 210-42. Therefore, the dimension L12 of the plating through hole (PTH) TH12 is smaller than the dimension L22 of the plating through hole (PTH) TH22.

In another aspect, the core layer structure 220D of the substrate 200D includes at least three core layers 202, 302, 402 and at least four pairs of PP layers 210 stacked on each other. In addition, the three core layers 202, 302, 402 are arranged in such a way that they alternate with the four pairs of PP layers 210. In some embodiments, the core layer structure 220D has a plating through hole (PTH) TH12 passing through the three core layers 202, 302, 402 and two of the four pairs of PP layers 210. In addition, the core layer structure 220D has a plating through hole (PTH) TH22 passing through the three core layers 202, 302, 402 and the four pairs of PP layers 210.

In yet another aspect, the core structure 220D of the substrate 200D includes N core layers (e.g., the core layers 202, 302 and 402) stacked on each other, wherein N is an integer greater than or equal to 3. The core structure 220D further includes 2N+2 Prepreg (PP) layers 210, a plating through hole (PTH) TH12 and a plating through hole (PTH) TH22. The 2N+2 Prepreg (PP) layers are disposed on the N core layers. In addition, the top surface and the bottom surface of each of the N core layers (e.g., the top surface 202T and the bottom surface 202B of the core layer 202 and the top surface 302T and the bottom surface 302B of the core layer 302) are directly covered by the 2 PP layers 210 only. The plating through hole (PTH) TH21 passes through the 2N−2 PP layers 210. The plating through hole (PTH) TH22 passes through the 2N+2 PP layers 210.

In this embodiment, two terminals 404T1, 404T2 of the plating through hole (PTH) TH12 are not aligned with two corresponding terminals 406T1, 406T2 of the plating through hole (PTH) TH22 in the direction D100. For example, the two terminals 404T1, 404T2 of the plating through hole (PTH) TH12 may be close to the top surface 302T of the core layer 302 and the bottom surface 202B of the core layer 202, respectively. In addition, the two terminals 404T1, 404T2 of the plating through hole (PTH) TH12 may be exposed from the top surface 302T of the core layer 302 and the bottom surface 202B of the core layer 202, respectively. In some embodiments, the two terminals 406T1, 406T2 of the plating through hole (PTH) TH22 may be close to the top surface 220DT and the bottom surface 220DB of the core layer structure 220D, respectively. In addition, the two terminals 406T1, 406T2 of the plating through hole (PTH) TH22 may be exposed from the top surface 220DT and the bottom surface 220DB of the core layer structure 220D, respectively.

In some embodiments, the terminal 404T1 of the plating through hole (PTH) TH12 and the terminal 406T1 of the plating through hole (PTH) TH22 are close to opposite surfaces of the pair of PP layers 210 of the core layer redistribution layer 210-1. For example, the terminal 404T1 of the plating through hole (PTH) TH12 is close to a surface (also an inner surface 210-1B of the core layer redistribution layer 210-1) of the pair of PP layers 210 of the core layer redistribution layer 210-1 that is close to the top surface 302T of the core layer 302. The terminal 406T1 of the plating through hole (PTH) TH22 is close to a surface (also the top surface 220DT) of the pair of PP layers 210 of the core layer redistribution layer 210-1 that is close to the top surface 220DT of the core layer structure 220D.

In other words, the terminal 404T1 of the plating through hole (PTH) TH12 is close to an inner surface (also the inner surface 210-1B of the core layer redistribution layer 210-1) of the pair of PP layers 210 of the core layer redistribution layer 210-1 that is close to the core layer 302. The terminal 406T1 of the plating through hole (PTH) TH22 is close to an outer surface (also the top surface 220DT) of the pair of PP layers 210 of the core layer redistribution layer 210-1 that is away from the core layer 302.

Similarly, the terminal 404T2 of the plating through hole (PTH) TH12 and the terminal 406T2 of the plating through hole (PTH) TH22 are close to opposite surfaces of the pair of PP layers 210 of the core layer redistribution layer 210-2. For example, the terminal 404T2 of the plating through hole (PTH) TH12 is close to a surface (also an inner surface 210-2B of the core layer redistribution layer 210-2) of the pair of PP layers 210 of the core layer redistribution layer 210-2 that is close to the bottom surface 202B of the core layer 202. The terminal 406T2 of the plating through hole (PTH) TH22 is close to a surface (also the bottom surface 220DB) of the pair of PP layers 210 of the core layer redistribution layer 210-2 that is close to the bottom surface 220DB of the core layer structure 220D.

In other words, the terminal 404T2 of the plating through hole (PTH) TH12 is close to an inner surface (also the inner surface 210-2B of the core layer redistribution layer 210-2) of the pair of PP layers 210 of the core layer redistribution layer 210-2 that is close to the core layer 202. The terminal 406T1 of the plating through hole (PTH) TH22 is close to an outer surface (also the bottom surface 220DB) of the pair of PP layers 210 of the core layer redistribution layer 210-1 that is away from the core layer 202.

In some embodiments, the plating through holes (PTH) TH11, TH21, TH12, TH22 may have the same or similar structures, materials and processes.

In this embodiment, the electrical connections among the plating through holes (PTHs) TH12, the core layer redistribution layers 210-1, 210-2 and the substrate redistribution layer 230-1, 230-2 may refer to the electrical connections among the plating through holes (PTHs) TH11, the core layer redistribution layers 210-1, 210-2 and the substrate redistribution layer 230-1, 230-2 of the semiconductor structures 500A to 500C and are not repeated for brevity. In addition, the electrical connections among the plating through holes (PTHs) TH22 and the substrate redistribution layer 230-1, 230-2 may refer to the electrical connections among the plating through holes (PTHs) TH21 and the substrate redistribution layer 230-1, 230-2 of the semiconductor structures 500A to 500C and are not repeated for brevity.

Similar to semiconductor structures 500B and 500C, the core structure 220D may have only one type of plating through hole (PTH) of plating through holes (PTHs) TH21 or plating through holes (PTHs) TH22.

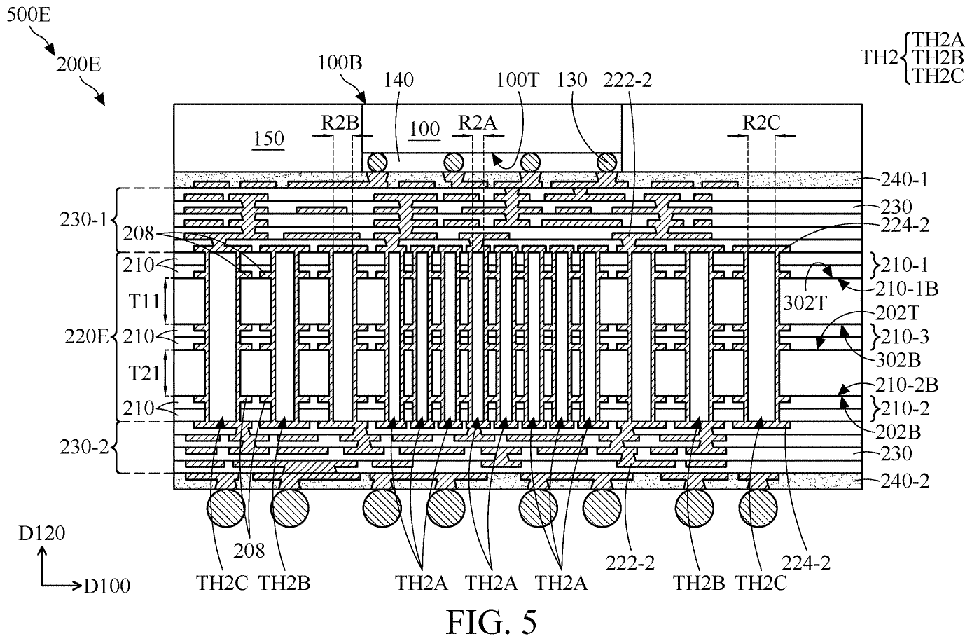

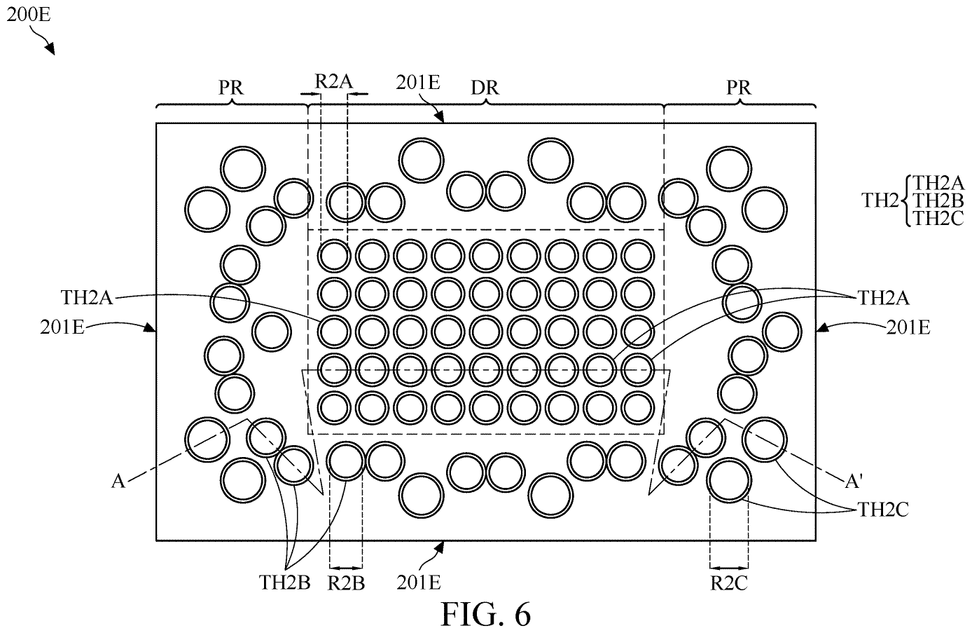

FIG. 5 is a schematic cross-sectional view of a semiconductor package 500E in accordance with some embodiments of the disclosure. FIG. 6 is a schematic top view of a substrate 200E of the semiconductor package 500E of FIG. 5 in accordance with some embodiments of the disclosure. Elements of the embodiments that are the same or similar to those previously described with reference to FIG. 3 are not repeated herein, in the interests of brevity.

As shown in FIG. 5, the semiconductor package 500E includes a substrate 200E (schematic cross-sectional view of the substrate 200E is taken along the line A-A′ of FIG. 5) and a die 100. In a top view as shown in FIG. 5, the substrate 200E has a die region DR and a peripheral region PR surrounding the die region DR. The die region DR is provided for the die 100 mounted directly on it. In some embodiments, the die region DR may also serve as a projection region of the die 100 on the top surface 200ET (or the bottom surface 200EB) of the substrate 200E in the direction D120.

In some embodiments, the substrate 200E includes that a core structure 220E and substrate redistribution layers (RDLs) 230-1 and 230-2. In addition, the core structure 220E includes two core layers 202, 302, core redistribution layers (RDLs) 210-1 and 210-2 and 210-3. The substrate 200E may also be called a multi-layer duo core substrate.

As shown in FIG. 5, the core structure 220E of the substrate 200E has separated plating through holes (PTHs) TH2 (including plating through holes (PTHs) TH2A, TH2B, and TH2C) embedded it. In some embodiments, the plating through hole (PTH) TH2 passes through the core structure 220E including the core layers 202 and 302, the pair of PP layers 210 of the core redistribution layers 210-1, the pair of PP layers 210 of the core redistribution layer 210-2 and the pair of PP layers 210 of the core redistribution layer 210-3. In some embodiments, the plating through holes (PTHs) TH2A, TH2B, and TH2C may be formed in the same process.

As shown in FIG. 5, the plating through holes (PTHs) TH2A are disposed in the die region DR of the substrate 200E. The plating through holes (PTHs) TH2B and TH2C are disposed in the peripheral region PR of the substrate 200E. In some embodiments, the plating through holes (PTHs) TH2 are disposed out of the die region DR and surrounding the die region DR. In addition, the plating through holes (PTHs) TH2B are disposed between the plating through holes (PTHs) TH2A and the plating through holes (PTHs) TH2C in the direction D100.

In some embodiments, in a top view (in the direction D100), the plating through holes (PTHs) TH2A are completely covered by the die 100. In addition, the plating through holes (PTHs) TH2B and TH2C are exposed form the die 100. In some embodiments, the plating through holes (PTHs) TH2B and TH2C are closer to an edge of the substrate 200E than the plating through holes (PTHs) TH2A. In some embodiments, the plating through holes (PTHs) TH2C are closer to an edge 201E of the substrate 200E than the plating through holes (PTHs) TH2B. Alternatively, the plating through holes (PTHs) TH2B are closer to an edge 201E of the substrate 200E than the plating through holes (PTHs) TH2C.

In some embodiments, in the direction D100 (also serve as a radial direction of the plating through holes (PTHs) TH2), the dimension R2A (or the diameter R2A) of the plating through hole (PTH) TH2A in the die region DR is smaller than a dimension R2B (or the diameter R2B) of the plating through hole (PTH) TH2B and a dimension R2C (or the diameter R2C) of the plating through hole (PTH) TH2C in the peripheral region PR.

In other words, the dimension R2A (or the diameter R2A) of the plating through hole (PTH) TH2A completely covered by the die 100 is smaller than the dimension R2B (or the diameter R2B) of the plating through hole (PTH) TH2B and the dimension R2C (or the diameter R2C) of the plating through hole (PTH) TH2C exposed form the die 100.

For example, the diameter R2A of the plating through hole (PTH) TH2A may range between about 100 μm to about 200 μm, for example, about 150 μm. The diameter R2B of the plating through hole (PTH) TH2B may range between about 125 μm to about 225 μm, for example, about 175 μm. The diameter R2C of the plating through hole (PTH) TH2C may range between about 150 μm to about 250 μm, for example, about 200 μm.

In some embodiments, the differences between the plating through hole (PTH) TH2A and the plating through hole (PTH) TH2B may range between about 10 μm to about 50 μm, for example, about 25 μm. In addition, the differences between the plating through hole (PTH) TH2BA and the plating through hole (PTH) TH2C may range between about 10 μm to about 50 μm, for example, about 25 μm.

In some embodiments, in the direction D100 (also serve as a radial direction of the plating through holes (PTHs) TH2), the dimension R2B (or the diameter R2B) of the plating through hole (PTH) TH2B is smaller than the dimension R2C (or the diameter R2C) of the plating through hole (PTH) TH2C in the peripheral region PR.

In some embodiments, the plating through holes (PTHs) TH2A in the die region DR and having the smallest diameter (e.g., the diameter R2A) are used for power transmission and/or grounding (GND). Due to the reduced diameter, a greater number of PTHs TH2A can be arranged within the die region DR, thereby increasing the PTH density and providing sufficient power/ground conduction capability to satisfy design requirements (e.g., current-carrying capacity and return-path needs), and consequently improving power integrity). The positions of the plating through holes (PTHs) TH2A may be arranged corresponding to the power pads (not shown) of the die 100 to further improve power integrity. For example, the plating through holes (PTHs) TH2A may be arranged directly under the power pads (not shown) of the die 100.

In some embodiments, the plating through holes (PTHs) TH2B in the peripheral region PR and having the larger diameter (e.g., the diameter R2B) than the plating through holes (PTHs) TH2A in the die region DR are used for signal transmission only to further improve signal integrity. In other words, the plating through holes (PTHs) (e.g., the plating through holes (PTHs) TH2B) used for signal transmission are exposed from the die 100 in the top view. It should be noted that no plating through hole (PTH) used for signal transmission is disposed in the die region DR. For signal transmission requirements, the substrate 200E may include at least one pair of plating through holes (PTHs) TH2B.

In some embodiments, the plating through holes (PTHs) TH2C in the peripheral region PR and having the largest diameter (e.g., the diameter R2C) are used for power transmission and/or grounding (GND). Because the diameter R2C is relatively large, each PTH TH2C provides a larger conductive cross-sectional area, thereby reducing via resistance (and corresponding transmission loss/IR drop) and providing a lower-impedance power/ground path than other paths (e.g., those including the PTH TH2B), so as to further improve power integrity).

In this embodiment, all the plating through hole (PTH) TH2A, the plating through holes (PTH) TH2B and the plating through holes (PTH) TH2C have the same or similar structure (the length) to the plating through hole (PTH) TH11, which is formed passing through the core structure 220A including the core layers 202 and 302, and the pair of PP layers 210 of the core redistribution layer 210-3.

Alternatively, all the plating through hole (PTH) TH2A, the plating through holes (PTH) TH2B and the plating through hole (PTH) TH2C may have the same or similar structure to the plating through holes (PTH) TH21, which is formed passing through the core structure 220A including the core layers 202 and 302, the pair of PP layers 210 of the core redistribution layers 210-1, the pair of PP layers 210 of the core redistribution layer 210-2 and the pair of PP layers 210 of the core redistribution layer 210-3.

Alternatively, any of the plating through hole (PTH) TH2A, the plating through hole (PTH) TH2B and the plating through hole (PTH) TH2C may have the same structure as the plating through hole (PTH) TH11 or the plating through hole (PTH) TH21.

Alternatively, any the groups of the plating through holes (PTHs) TH2A, the plating through holes (PTHs) TH2B and the plating through holes (PTHs) TH2C may have structures as a combination of the plating through hole (PTH) TH11 and the plating through holes (PTH) TH21.

In another aspect, the core structure 220E of the substrate 200E includes N core layers stacked on each other, wherein N is an integer greater than or equal to 3. The core structure 220E further includes 2N+2 Prepreg (PP) layers 210, a plating through hole (PTH) TH2. The 2N+2 Prepreg (PP) layers are disposed on the N core layers. In addition, the top surface and the bottom surface of each of the N core layers are directly covered by the 2 PP layers 210 only. The plating through hole (PTH) TH2 (including plating through holes (PTHs) TH2A to TH2C) passes through the 2N−2 PP layers 210 or the 2N+2 PP layers 210.

The semiconductor packages 500A to 500E has the following advantages. In the conventional single-core package, the ground (GND) resonator generated by the ground structure (e.g., a grounding PTH passing through the single-core) next to the signal line (e.g., a signal PTH) will have a negative impact on the signal transmission. The resonant frequency of the ground structure will be the transmission zero (zero output for finite input) of the signal transmission. Since the resonant frequency of the ground (GND) resonator is inversely proportional to the thickness of the core layer (i.e., the resonant frequency directly proportional to the reciprocal of the thickness of the core layer), the substrate may have higher resonance frequencies by reducing the thickness of the core layer. Compared with the conventional single-core package, the multi-layer core substrate approach described in the present disclosure can effectively increase the resonant frequency while maintaining the total sub-state thickness (to keep the mechanical strength).

In addition, through the multi-layer core structure (e.g., the multi-layer core structures 220A to 220E), the resonance cavity caused by the conventional single grounding structure is divided into two or three smaller and vertical stacked resonance cavities (or more resonance cavities) passing through different core layers (e.g., the core layer 202, 302, or 402), thereby pushing the resonance frequency of the grounding structure to a higher frequency (increasing the resonance frequency) and increasing its transmission bandwidth. The resonance frequency of the structure is inversely proportional to the size of the resonance cavity. The smaller the size (directly proportional to the thickness of the core layer 202, 302, or 402), the higher the frequency of the grounding structure resonance, and the wider the bandwidth or higher the frequency of the signal transmission. The multi-layer core and PP-layer packaging substrate structure of the embodiments enables the package substrate to support higher-frequency applications. Accordingly, the package substrate and the resulting semiconductor package provide a broader usable frequency range and are suitable for a wider variety of application scenarios.

Furthermore, since the core structure (e.g., the core structures 220A to 220E) is a composite structure composed of the multi-core layers (e.g., the core layer 202, 302, and 402) and the pairs of PP layers 210 disposed on opposite surfaces of the core layers, the mechanical strength of the substrate (e.g., the substrates 200A to 200E) is improved. In addition, the plating through holes (PTHs) having different dimensions in an extending direction and/or a radial direction (e.g., the plating through holes (PTHs) TH11, TH21, TH2A, TH2B and TH2C) may form the conductive paths suitable for power transmission, signal transmission and grounding. Therefore, the semiconductor package (e.g., the semiconductor packages 500A to 500E) can balance between power integrity and signal integrity.

Moreover, the semiconductor package (e.g., the semiconductor package to 500E) may arrange the plating through holes (PTHs) (e.g., the plating through holes (PTHs) TH2A) in the die region (e.g., the die region DR) and having the smallest diameter (e.g., the diameter R2A) are used for power transmission and/or grounding (GND) to further improve power integrity. The semiconductor package (e.g., the semiconductor package to 500E) may further arrange the plating through holes (PTHs) (e.g., the plating through holes (PTHs) TH2B and TH2C) and having the larger diameter (e.g., the diameter R2B) than the plating through holes (PTHs) in the die region. In the peripheral region PR, the plating through holes (PTHs) (e.g., the plating through holes (PTHs) TH2B) having smaller diameter (e.g., the diameter R2B) are used for signal transmission only to further improve signal integrity. In the peripheral region PR, the plating through holes (PTHs) (e.g., the plating through holes (PTHs) TH2C) having larger diameter (e.g., the diameter R2C) are used for power transmission and/or grounding (GND) to further improve power integrity.

Embodiments provide a semiconductor package. The semiconductor package includes a substrate and a die. The die is mounted on the substrate. The substrate includes a first core layer, a second core layer, and a first pair of Prepreg (PP) layers. The second core layer is stacked on the first core layer. The first pair of Prepreg (PP) layers is disposed between the first core layer and the second core layer.

In some embodiments, the substrate further includes a second pair of Prepreg (PP) layers disposed on a bottom surface of the first core layer and opposite the first pair of PP layers.

In some embodiments, the substrate further includes a third pair of Prepreg (PP) layers disposed on a top surface of the second core layer and opposite the first pair of PP layers.

In some embodiments, the substrate further includes a first plating through hole (PTH) passing through the first core layer, the second core layer and the first pair of PP layers between the first core layer and the second core layer.

In some embodiments, the substrate further includes a second plating through hole (PTH) passing through the first core layer, the second core layer, the first pair of PP layers, the second pair of PP layers and the third pair of PP layers.

In some embodiments, a first dimension of the first PTH is smaller than a second dimension of the second PTH in an extending direction of the first PTH or the second PTH.

In some embodiments, a first dimension of the first PTH is smaller than a second dimension of the second PTH in a radial direction of the first PTH or the second PTH.

In some embodiments, a first terminal of the first PTH and a second terminal of the second PTH corresponding to the first terminal are close to opposite surfaces of the second pair of PP layers or the third pair of PP layers.

In some embodiments, the substrate further includes first dielectric layers disposed on the second pair of Prepreg (PP) layers and opposite the first core layer. The first dielectric layers and the first additional two Prepreg (PP) layers are made of different materials

In some embodiments, the first dielectric layers are formed of Ajinomoto BuildUp Film (ABF).

In some embodiments, the substrate further includes a first via and a second via. The first via is disposed in the second pair of Prepreg (PP) layers and coupled to the first PTH by a first conductive layer covered by the second pair of Prepreg (PP) layers. The second via is disposed in the first dielectric layers and coupled to the second PTH by a second conductive layer covered by the first dielectric layers.

In some embodiments, the first via has a first diameter, and the second via has a second diameter different from the first diameter.

In some embodiments, the substrate further includes a third PTH, a fourth PTH and a fifth PTH. The third PTH is disposed in a die region of the substrate. The fourth PTH is disposed in a peripheral region of the substrate, where the peripheral region surrounds the die region. The fifth PTH is disposed in the peripheral region of the substrate. A third diameter of the third PTH is less than a fourth diameter of the fourth PTH, and the fourth diameter of the fourth PTH is less than a fifth diameter of the fifth PTH.

In some embodiments, the fourth PTH is disposed between the third PTH and the fifth PTH.

In some embodiments, the third PTH and the fifth PTH are used for power transmission and/or grounding (GND).

In some embodiments, the fourth PTH is used for signal transmission.

In some embodiments, the substrate includes at least one pair of third PTHs.

In some embodiments, any of the third PTH, the fourth PTH and the fifth PTH has the same structure as the first PTH or the second PTH.

In some embodiments, the substrate further includes a third core layer disposed between the first core layer and the second core layer.

Embodiments provide a semiconductor package. The semiconductor package includes a substrate and a die. The substrate includes a core structure. The core structure includes at least two cores and at least three pairs of Prepreg (PP) layers stacked on each other. The cores are arranged in such a way that they alternate with the at least three pairs of PP layers. The core structure has a first plating through hole (PTH) passing through the cores and one of the three pairs of PP layers, and a second plating through hole (PTH) passing through the cores and the three pairs of PP layers. The die is mounted on the substrate and coupled to the first PTH and the second PTH.

Embodiments provide a semiconductor package. The semiconductor package includes a substrate and a die. The substrate includes N core layers, 2N+2 Prepreg (PP) layers, a first plating through hole (PTH), and a second plating through hole (PTH), wherein N is an integer greater than or equal to 2. The N core layers are stacked on each other. The 2N+2 Prepreg (PP) layers are disposed on the N core layers. A top surface and a bottom surface of each of the N core layers are directly covered by the 2 PP layers only. The first plating through hole (PTH) passes through the 2N−2 PP layers. The second plating through hole (PTH) passes through the 2N+2 PP layers. The die is mounted on the substrate and coupled to the first PTH and the second PTH.

While the disclosure has been described by way of example and in terms of the preferred embodiments, it should be understood that the disclosure is not limited to the dis-closed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor package comprising:
a substrate; and
a die mounted on the substrate, wherein the substrate comprises:
a first core layer;
a second core layer stacked on the first core layer; and
a first pair of Prepreg (PP) layers disposed between the first core layer and the second core layer.

2. The semiconductor package as claimed in claim 1, wherein the substrate further comprises:
a second pair of Prepreg (PP) layers disposed on a bottom surface of the first core layer and opposite the first pair of PP layers.

3. The semiconductor package as claimed in claim 2, wherein the substrate further comprises:
a third pair of Prepreg (PP) layers disposed on a top surface of the second core layer and opposite the first pair of PP layers.

4. The semiconductor package as claimed in claim 3, wherein the substrate further comprises:
a first plating through hole (PTH) passing through the first core layer, the second core layer and the first pair of PP layers.

5. The semiconductor package as claimed in claim 4, wherein the substrate further comprises:
a second plating through hole (PTH) passing through the first core layer, the second core layer, the first pair of PP layers, the second pair of PP layers and the third pair of PP layers.

6. The semiconductor package as claimed in claim 5, wherein a first dimension of the first PTH is smaller than a second dimension of the second PTH in an extending direction of the first PTH or the second PTH.

7. The semiconductor package as claimed in claim 5, wherein a first dimension of the first PTH is smaller than a second dimension of the second PTH in a radial direction of the first PTH or the second PTH.

8. The semiconductor package as claimed in claim 5, wherein a first terminal of the first PTH and a second terminal of the second PTH corresponding to the first terminal are close to opposite surfaces of the second pair of PP layers or the third pair of PP layers.

9. The semiconductor package as claimed in claim 5, wherein the substrate further comprises:
first dielectric layers disposed on the second pair of Prepreg (PP) layers and opposite the first core layer, wherein the first dielectric layers and the first additional two Prepreg (PP) layers are made of different materials.

10. The semiconductor structure as claimed in claim 9, wherein the substrate further comprises:
a first via disposed in the second pair of Prepreg (PP) layers and coupled to the first PTH by a first conductive layer covered by the second pair of Prepreg (PP) layers; and
a second via disposed in the first dielectric layers and coupled to the second PTH by a second conductive layer covered by the first dielectric layers.

11. The semiconductor structure as claimed in claim 11, wherein the first via has a first diameter, and the second via has a second diameter different from the first diameter.

12. The semiconductor package as claimed in claim 1, wherein the substrate further comprises:
a third PTH disposed in a die region of the substrate;
a fourth PTH disposed in a peripheral region of the substrate, where the peripheral region surrounds the die region; and
a fifth PTH disposed in the peripheral region of the substrate,
wherein a third diameter of the third PTH is less than a fourth diameter of the fourth PTH, and the fourth diameter of the fourth PTH is less than a fifth diameter of the fifth PTH.

13. The semiconductor package as claimed in claim 12, wherein the fourth PTH is disposed between the third PTH and the fifth PTH.

14. The semiconductor package as claimed in claim 12, wherein the third PTH and the fifth PTH are used for power transmission and/or grounding (GND).

15. The semiconductor package as claimed in claim 12, wherein the fourth PTH is used for signal transmission.

16. The semiconductor package as claimed in claim 12, wherein the substrate comprises at least one pair of third PTHs.

17. The semiconductor package as claimed in claim 5, wherein the substrate further comprises:
a third core layer disposed between the first core layer and the second core layer.

18. A semiconductor package, comprising:
a substrate, wherein the substrate comprises:
a core structure, wherein the core structure comprises:
at least two cores and at least three pairs of Prepreg (PP) layers stacked on each other, wherein the at least two cores are arranged in such a way that they alternate with the at least three pairs of PP layers,
wherein the core structure has a first plating through hole (PTH) passing through the at least two cores and one of the three pairs of PP layers, and a second plating through hole (PTH) passing through the at least two cores and the three pairs of PP layers; and
a die mounted on the substrate and coupled to the first PTH and the second PTH.

19. A semiconductor package, comprising:
a substrate, wherein the substrate comprises:
N core layers stacked on each other, wherein N is an integer greater than or equal to 2;
2N+2 Prepreg (PP) layers disposed on the N core layers, wherein a top surface and a bottom surface of each of the N core layers are directly covered by the 2 PP layers only;
a first plating through hole (PTH) passing through the 2N−2 PP layers; and
a second plating through hole (PTH) passing through the 2N+2 PP layers; and
a die mounted on the substrate and coupled to the first PTH and the second PTH.
